(19) United States
(12) Patent Application Publication
(10) Pub. No.: US 2006/0033104 A1
(43) Pub. Date: Feb. 16, 2006

(54) Thin film transistor, method of manufacturing thin film transistor, and display device

(75) Inventors: Yoshiaki Nakazaki, Yokohama-shi (JP); Fumiki Nakano, Yokohama-shi (JP); Genshiro Kawachi, Yokohama-shi (JP); Terunori Warabisako, Yokohama-shi (JP); Masayuki Jyumonji, Yokohama-shi (JP); Hiroyuki Ogawa, Yokohama-shi (JP); Masato Hiramatsu, Yokohama-shi (JP); Tomoya Kato, Yokohama-shi (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: Advanced LCD Technologies Dev. Ctr. Co., Ltd., Yokohama-shi (JP)

(21) Appl. No.: 11/197,637

(22) Filed: Aug. 5, 2005

(30) Foreign Application Priority Data
Aug. 10, 2004 (JP) 2004-233344
Nov. 11, 2004 (JP) 2004-357389

(51) Int. Cl. H01L 29/04; H01L 29/76; H01L 27/12

(52) U.S. Cl. 257/64; 257/66; 257/347

(57) ABSTRACT

There is disclosed a thin film transistor having a source region, a channel region, and a drain region in a semiconductor thin film whose crystals have grown in a transverse direction, the thin film transistor having a gate insulating film and a gate electrode in an upper part of the channel region, wherein a channel-region-side edge portion of the drain region or the source region is disposed in such a manner as to be positioned in the vicinity of an end position of lateral growth.

### CROSS-REFERENCE TO RELATED APPLICATIONS

This application is based upon and claims the benefit of priority from prior Japanese Patent Applications No. 2004-233344, filed Aug. 10, 2004; and No. 2004-357389, filed Nov. 11, 2004, the entire contents of both of which are incorporated herein by reference.

### BACKGROUND OF THE INVENTION

1. Field of the Invention

The present invention relates to a thin film transistor, a method of manufacturing a thin film transistor, and a display device.

2. Description of the Related Art

An amorphous-silicon thin film or a poly-silicon thin film has heretofore been used in a semiconductor thin film of a thin film transistor (TFT) for use in a switching element which controls a voltage to be applied, for example, to a pixel of a liquid-crystal display (LCD), a control circuit and the like.

The TFT in which the poly-silicon thin film is formed as the semiconductor thin film has mobility of an electron or a hole which moves in a channel region, which is higher than that of the TFT in which the amorphous-silicon thin film is formed as the semiconductor thin film. Therefore, switching speed of the transistor using the poly-silicon thin film is higher than that of the transistor using the amorphous-silicon thin film. Therefore, not only a pixel selection circuit of the LCD but also a peripheral driving circuit for driving the LCD may comprise the thin-film transistors. Furthermore, there is an advantage that design margin of another component can be broadened. When peripheral driving circuits such as a driver circuit and a DAC are incorporated in a display, cost reduction, precision enhancement, and miniaturization are possible.

### BRIEF SUMMARY OF THE INVENTION

The present inventors has developed a liquid crystal display in which a TFT is formed on a single crystal silicon thin film to thereby raise mobility of an electron or a hole moving through a channel region. This development problem lies in that a large particle diameter crystallized region is formed having a size capable of manufacturing one or several TFTs in an amorphous-silicon thin film. As a method of forming the large grain size crystallized region, crystallization methods have been proposed including: “Preparation of Ultra-Large Grain Silicon Thin-Films by Excimer-Laer” Masakiyo MATSUMURA, Surface Science, Vol. 21, No. 5 pp. 278 to 287, 2000; and “Method of forming large Crystal Grain Si Film by Excimer Laser Light Irradiation” Masakiyo MATSUMURA, Applied Physics, Vol. 71, No. 5 pp. 543 to 547, 2000. The present patent applicant has researched industrialization of this large grain size crystallization technique. When the industrialization of the large grain size crystallized region is realized, in the LCD, it is possible to manufacture not only a changeover switching transistor of each pixel but also memory circuits such as DRAM and SRAM, a logical calculation circuit and the like on a glass substrate, and energy saving and miniaturization of the LCD are possible.

As a result of intensive research, the present inventors have developed an industrialization technique of large grain size lateral growth. Furthermore, a manufacturing technique for forming a higher-performance TFT in this large grain size lateral growth region has been developed. It has been found that the surface of single-crystal silicon on which the large grain size crystal has grown is not a flat thin film in a micro manner unlike a silicon wafer. It has also been found that a crystal grain boundary is complicated, and therefore a desired characteristic cannot be obtained, when the TFT is simply formed in a crystallized region. An object of the present invention is to provide a thin film transistor capable of manufacturing a TFT having higher mobility of an electron (or a hole), a method of manufacturing a thin film transistor, and a display device.

According to the present invention, there is provided a thin film transistor having a source region, a channel region, and a drain region in a semiconductor thin film whose grains have grown in a lateral direction crossing a thickness direction, and the thin film transistor having a gate insulating film and a gate electrode in an upper part of the channel region,
wherein a channel-region-side edge portion of at least one of the drain region and the source region is disposed in such a manner as to be positioned in the vicinity of an end position of the lateral growth. The thin film transistor constituted in this manner is capable of manufacturing a TFT having higher mobility of an electron (or a hole).

According to the present invention, there is provided a thin film transistor having a source region, a channel region, and a drain region in a semiconductor thin film having an inclined face raised in a growth edge direction of grains which have grown in a lateral direction crossing a thickness direction, the thin film transistor having a gate insulating film and a gate electrode in an upper part of the channel region,
wherein a channel-region-side edge portion of at least one of the drain region and the source region is disposed in such a manner as to be positioned in the vicinity of a vertex of the inclined face. The thin film transistor constituted in this manner is capable of manufacturing a TFT having higher mobility of an electron (or a hole) in a crystallized region.

According to the present invention, there is provided a thin film transistor having a source region, a channel region, and a drain region in a semiconductor thin film having an inclined face whose film thickness increases toward a lateral growth edge point in a silicon film growing in a lateral growth direction from a lateral growth start position, the thin film transistor having a gate insulating film and a gate electrode in an upper part of the channel region,
wherein a channel-region-side edge portion of at least one of the drain region and the source region is disposed in such a manner as to be positioned in the vicinity of a vertex of the semiconductor thin film whose film thickness increases. The thin film transistor constituted in this manner is capable of manufacturing a TFT having higher mobility of an electron (or a hole) in a crystallized region.

According to the present invention, there is provided a method of manufacturing a thin film transistor, comprising: a step of irradiating a non-single crystal semiconductor film with modulation laser light having inverted-peaked light intensity distribution to form a crystallized semiconductor thin film whose section has a peaked shape in an irradiated region; and a step of positioning a channel-region-side edge portion of at least one of a drain region and a source region in the vicinity of a vertex portion of the peaked-shaped crystallized semiconductor thin film to form the thin film transistor in the positioned portion. This method of manufacturing the thin film transistor is capable of manufacturing a TFT having higher mobility of an electron (or a hole) in a crystallized region.

In a display device of the present invention, a peripheral circuit portion requiring a high-speed operation of a signal line driving circuit or a scanning line driving circuit comprises: the thin film transistor. This display device is capable of realizing a system display containing active elements such as a peripheral circuit portion, a memory circuit portion and the like.

According to the present invention, a TFT having higher mobility of an electron (or a hole) can be obtained.

### BRIEF DESCRIPTION OF THE SEVERAL VIEWS OF THE DRAWING

FIG. 1 is a partially cutout sectional view showing a constitution of a thin film transistor of the present invention;

FIG. 2 is a flowchart showing steps of manufacturing a TFT of FIG. 1 in order of steps;

FIG. 3 is a constitution diagram of a crystallization device, showing crystallization steps of FIG. 2;

FIG. 4 is a constitution diagram specifically showing an optical illumination system of FIG. 3;

FIGS. 5A to 5D are explanatory views showing a substrate structure during crystallization by the crystallization device of FIG. 2, and a shape of a crystallized semiconductor thin film;

FIG. 6 is a microscope photograph showing a flat layout structure of the TFT;

FIGS. 7A to 7G are sectional views showing an example of the TFT manufacturing steps of FIG. 2 in order of steps;

FIG. 8 is a sectional photograph of the TFT shown in FIG. 7G;

FIG. 9 is a flat photograph of the TFT shown in FIG. 8;

FIG. 10 is a characteristic diagram showing mobility characteristics of a large number of TFTs obtained by the steps of FIGS. 7A to 7G;

FIG. 11 is a circuit constitution diagram showing an example in which the thin film transistor of FIG. 1 is applied to a LCD;

FIG. 12 is a flat circuit diagram enlarging/showing a part of the LCD of FIG. 11;

FIG. 13 is a characteristic diagram of an n-channel-type TFT showing that the mobility characteristic of the thin film transistor differs with a drain edge forming position of a thin film transistor according to another example of the thin film transistor of FIG. 1;

FIG. 14 is a characteristic diagram of a p-channel-type TFT showing that the mobility characteristic of the thin film transistor differs with the drain edge forming position of another thin film transistor of FIG. 13; and

FIG. 15 is a characteristic diagram showing a relation of a drain current with respect to a gate voltage at a time when the drain edge forming position of the thin film transistor according to another example of the thin film transistor of FIG. 1 is changed to form the thin film transistor.

### DETAILED DESCRIPTION OF THE INVENTION

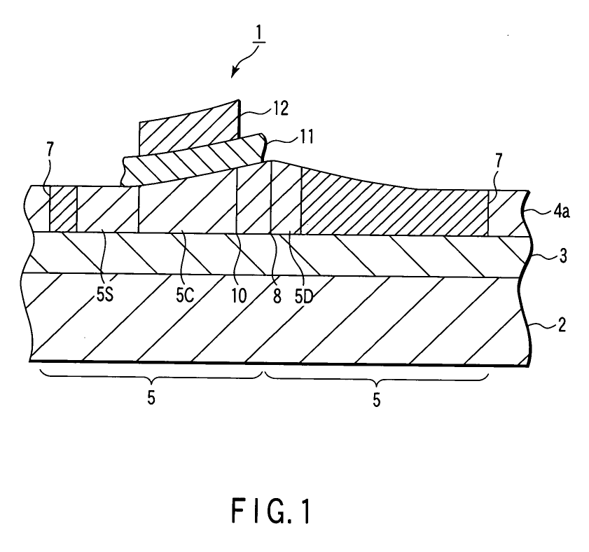

Next, an embodiment of a thin film transistor according to the present invention will be described with reference to FIG. 1. FIG. 1 is an enlarged sectional view of a region in which the thin film transistor is formed. This embodiment has the following characteristics.

It has been found that in a crystallized region where a non-single-crystal semiconductor layer is crystallized in a transverse direction, crystals grow in a horizontal direction from a lateral growth start position, and the region has a raised shape in a lateral growth edge position. That is, the crystallized region in which the non-single-crystal semiconductor layer is crystallized in the lateral direction, a silicon film which grows in a lateral growth direction from the lateral growth start position has an inclined face along which film thickness increases toward a lateral growth edge point. It has been found that, in this crystallized region, electron or hole mobility (μmaX) in a channel region increases in the lateral growth direction of a TFT, and remarkably increases in the vicinity of a lateral growth edge portion. This characteristic is utilized in this embodiment. That is, when the TFT is formed in this crystallized region, the TFT is positioned and formed in such a manner as to dispose a channel-region-side edge portion of a drain region or a source region in the vicinity of the lateral growth edge position, and then the electron or hole mobility (μmaX) is maximized.

Furthermore, the crystallized region where the non-single-crystal semiconductor layer is crystallized in the lateral direction is also a semiconductor thin film having the inclined face whose grains grow in the horizontal direction from the lateral growth start position and which is raised toward the lateral growth edge position. Although a reason is not clear, laser fluence is large, and the crystals collide against one another in the raised portion. Therefore, this portion is supposed to be a region in which film stress is large, abrasion is also caused, and characteristic degrades The channel-region-side edge portion of the drain region or the source region is disposed in the vicinity of the vertex of the inclined face. Furthermore, the crystallized region where the non-single-crystal semiconductor layer is crystallized in the lateral direction has the inclined face along which the film thickness monotonously increases in the horizontal direction (or lateral direction) from the lateral growth start position. The channel-region-side edge portion of the drain region or the source region is disposed in the vicinity of the vertex of the inclined face along which the film thickness monotonously increases. Examples of the non-single-crystal semiconductor film include a poly-crystal semiconductor film, an amorphous semiconductor film and the like.

Next, a specific constitution example of the TFT which drives a LCD will be described with reference to FIG. 1. A TFT 1 of FIG. 1 has a structure of a top gate type thin film transistor. A substrate may be an insulator, semiconductor substrate, or metal substrate. An insulating film, for example, a silicon oxide film 3 is disposed on an insulating substrate, for example, a glass substrate 2. The silicon oxide film 3 is a thermal oxide film, and is formed, for example, in a thickness of 1 μm. A non-single-crystal semiconductor film, for example, an amorphous silicon film 4 is disposed on the silicon oxide film 3. This amorphous silicon film 4 is formed of plasma CW, for example, into a thickness of 200 nm.

A crystallized region is disposed in the whole surface or a predetermined region of the amorphous silicon film 4. This crystallized region is a crystallized region 5 irradiated with a light beam having light intensity distribution having an inverted peak pattern, and having energy for melting the amorphous silicon film 4, for example, with KrF excimer laser light.

The crystallized region 5 crystallized by the laser light having the light intensity distribution having the inverted peak pattern obtains such a section shape that film thickness successively increases in a horizontal direction from a lateral growth start position 7, crystals grow, and a crystallized single-crystal silicon film is raised in the vicinity of a lateral growth edge position 8. The crystallized region 5 crystallized by laser light having a plurality of inverted-peak-patterned light intensity distributions has a peaked section shape in which the crystallized silicon film is raised in adjacent positive peak portions. The film whose predetermined position has been crystallized in this manner is defined as a semiconductor thin film 4a in this specification.

In this embodiment, a drain edge or a source end on the side of a channel region 5C of the TFT 1 to be formed is positioned and formed in such a manner as to be disposed in the vicinity of the lateral growth edge position 8. For example, as to a drain region 5D of the TFT 1, a drain edge 10 (side edge portion 10) on the side of the channel region 5C is positioned and disposed in the vicinity of the lateral growth edge position 8. The channel region 5C and a source region 5S are disposed continuously from the drain region 5D.

A gate insulating film 11, for example, a silicon oxide film is positioned with the channel region 5C, and disposed on the channel region 5C. This silicon oxide film has been thermally oxidized in a wet oxygen gas atmosphere, for example, at a temperature of 850° C. for 25 minutes. Furthermore, a gate electrode 12 is positioned with respect to the channel region 5C, and disposed on the gate insulating film 11. This gate electrode 12 ascends/tilts toward the lateral growth edge position 8. Therefore, in this embodiment, a bonded area of the source region 5S with respect to the channel region 5C is smaller than that of the channel region 5C of the drain region 5D. The TFT 1 is constituted in this manner. In this specification, it is assumed that examples of the TFT include a TFT having a TFT structure for use in applications such as a memory, capacitor, and resistance.

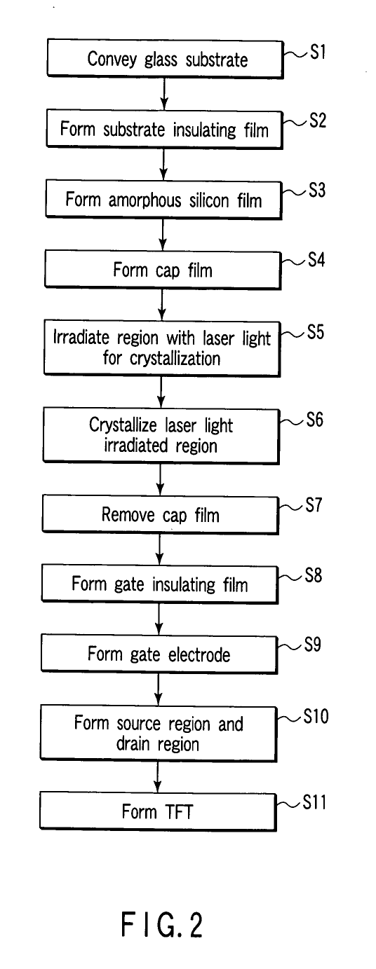

Next, an example of a method of manufacturing a TFT 1 will be described with reference to a flowchart of FIG. 2. The same parts as those of FIG. 1 are denoted with the same reference numerals, and detailed description is duplicated, and therefore omitted.

First, a step of manufacturing a substrate for crystallization is performed. A glass substrate 2 formed of quartz, non-alkali glass or the like is conveyed, and positioned and installed in a predetermined position in a plasma CVD device chamber (step S1). A substrate insulating film, for example, a silicon oxide film 3 grows in a gas phase on the glass substrate 2 by plasma CVD (step S2). This plasma CVD is performed, for example, on conditions at a substrate temperature of 500° C. for a deposition time of 40 minutes. Next, a non-single-crystal semiconductor film formed of amorphous silicon or poly-crystal silicon which is an object to be crystallized, for example, an amorphous silicon film 4 grows in a gas phase into a film thickness of 30 nm to 300 nm, about 200 nm, by plasma CVD on the silicon oxide film 3 (step S3).

This amorphous silicon film 4 is deposited on the silicon oxide film 3, for example, by a low pressure CVD (LP-CVD) process. For example, the amorphous silicon film 4 is an amorphous silicon film (a-Si) having a thickness of 200 nm. Conditions of the LP-CVD process are, for example, an Si₂H₆ atmosphere flow rate of 150 sccm, pressure of 8 Pa, substrate temperature of 450° C., and deposition time of 35 minutes. Here, the LP-CVD process was used, but additionally, for example, a low-temperature plasma CVD (PE-CVD) process may be used.

The non-single-crystal semiconductor thin film is a thin film of Ge, SiGe or the like in addition to the amorphous silicon film 4 (Si). The non-single-crystal semiconductor film may be formed by a sputtering device.

Next, a cap film having a transmitting property with respect to incident light, for example, a silicon oxide film is formed into a film thickness of 10 nm to 100 nm, for example, 10 nm by plasma CVD in order to form a large-grain-size crystallized region on the amorphous silicon film 4. The silicon oxide film is deposited on the amorphous silicon film 4, for example, by the LP-CVD process at a substrate temperature of 500° C. for a deposition time of ten minutes. The cap film is constituted of an insulating film having a function of accumulating heat. When the film is irradiated with laser light and crystallized, the film moderates a temperature drop speed of the non-single-crystal semiconductor thin film 2. The substrate for crystallization is manufactured in this manner (step S4).

Next, a crystallization step T is executed. The substrate for crystallization is aligned in a predetermined position of a crystallization device, and disposed. A predetermined crystallization position of the substrate for the crystallization conveyed into the crystallization device is irradiated with excimer laser light having a light intensity distribution having an inverted peak pattern (step S5), and a crystallized region having a large grain size is formed (step S6). The excimer laser light is, for example, KrF excimer laser having an energy density of 350 mJ/cm². Position information for the crystallization is stored beforehand in a computer. This computer automatically and successively moves and aligns a crystallization position in the substrate for the crystallization to irradiate the position with laser light for the crystallization, and the crystallization is performed to end the crystallization step T.

That is, in the crystallization step T, the surface of the cap film is irradiated with excimer pulse laser light having a light intensity distribution R having an inversed peak using a phase modulation excimer laser crystallization process. By laser irradiation with the pulse laser light, the irradiated region of the amorphous silicon film 4. In this molten region, temperature drops in a period of time when the pulse laser light is interrupted, a solidified position moves in a lateral direction (or horizontal direction), and crystals grow to form a crystallized region 5. As a result, the amorphous silicon film 4 is converted to a partially or entirely crystallized semiconductor thin film 4a. The irradiation with the pulse laser light may be performed once or a plurality of times, or a combination of irradiations with the pulse laser light and flash lamp light may be performed.

As shown in FIG. 1, in the crystallized region 5 formed in this manner, the crystals grow in a lateral direction from a lateral growth start position 7, and the region has a raised shape in a lateral growth edge position 8.

Next, the silicon oxide film of the cap film formed in order to form the TFT 1 in the large-grain-size crystallized region is removed (step S7). A process of removing the silicon oxide film can be performed by dry etching. This dry etching can be performed by an etching gas such as BCl₃ and CH₄.

Next, a step of manufacturing the TFT on the glass substrate 2 subjected to the crystallization step is executed. First, the glass substrate 2 is conveyed to a predetermined position of plasma CVD, and positioned and disposed. The silicon oxide film for forming a gate insulating film 11 is formed on the exposed surface of the semiconductor thin film of the conveyed glass substrate 2 (step S8).

Next, the glass substrate 2 on which the gate insulating film 11 has been formed is positioned and conveyed to a sputtering device which forms a conductor film for forming a gate electrode. Thereafter, for example, aluminum (Al) is formed as the gate electrode into a film (step S9). Next, the substrate is conveyed into a plasma etching device, and plasma-etched in order to form a gate electrode 12 (step S9).

Impurity ions for forming source and drain regions are implanted into the crystallized region with high concentration using the formed gate electrode 12 as a mask. As to the impurity ions, for example, phosphor is ion-implanted in an N-channel transistor, and boron is ion-implanted in a p-channel transistor. Thereafter, annealing is performed in a nitrogen atmosphere (e.g., at 600° C. for one hour), and impurities are activated to form the source region 5S and the drain region SD in the crystallized region as shown in FIG. 1. As a result, the channel region SC where a carrier moves is formed between the source region 5S and the drain region SD.

Next, an interlayer insulating layer is formed on the gate insulating film 11 and gate electrode 12. Contact holes are formed in the interlayer insulating layer in order to connect source and drain electrodes to the source and drain regions 5S, 5D, respectively (step S10).

Next, each contact hole is filled with materials, for example, metals constituting the gate electrode and the source and drain electrodes, and the material is also formed into a film on the interlayer insulating layer. The metal layer formed into the film on the interlayer insulating layer is etched into a predetermined pattern using a photolithography technique to form the source and drain electrodes, and a thin film transistor 1 is manufactured (step S11).

As apparent from the above-described manufacturing steps, a channel region C side edge portion of a source region S or a drain region D is positioned by the gate electrode 12. Therefore, a position where the gate electrode 12 is disposed is aligned and formed in the vicinity of the end position 8 of lateral growth.

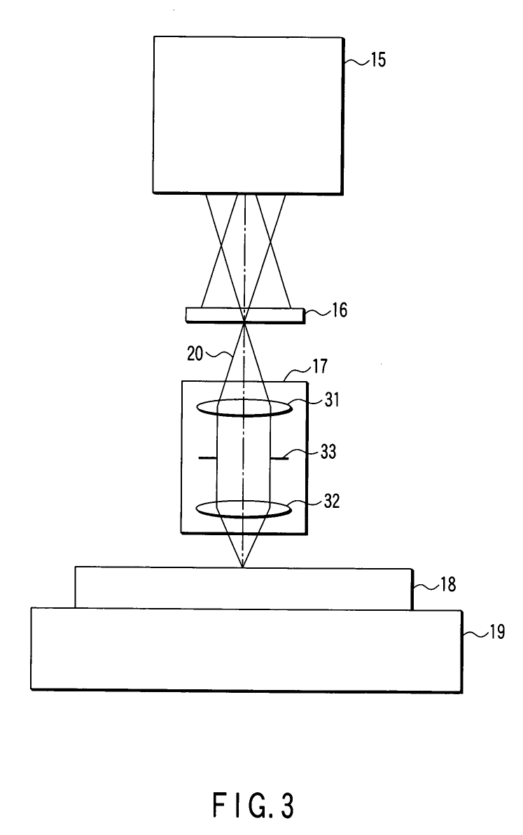

Next, an example of a crystallization device will be described specifically with reference to FIGS. 3 to 5. By the device, crystals grow in a lateral direction from the lateral growth start position 7, and a raised shape is obtained in the lateral growth edge position 8. The crystallization device is constituted of: an illumination system 15; a phase modulation element 16 disposed on an optical axis of the illumination system 15; an optical image forming system 17 disposed on the optical axis of the phase modulation element 16; and a stage 19 which holds a substrate 18 to be crystallized, disposed on the optical axis of the optical image forming system 17.

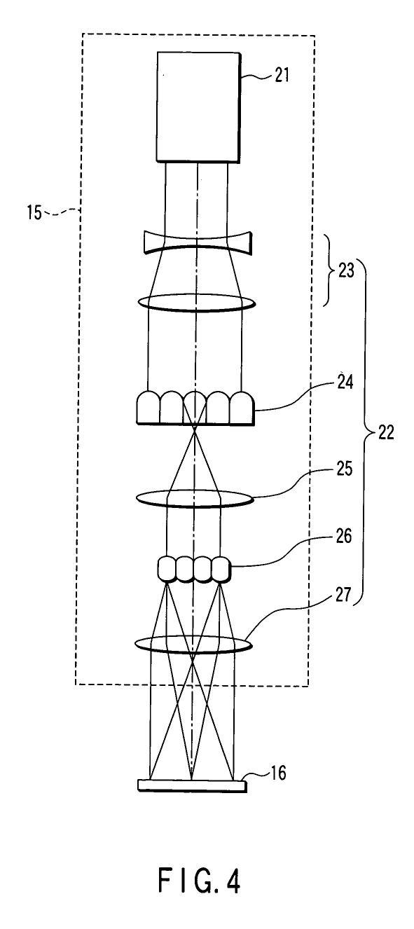

The illumination system 15 is an optical system shown in FIG. 4, and is constituted of a light source 21 and a homogenizer 22. The light source 21 comprises a KrF excimer laser light source 21 which supplies light having a wavelength of 248 nm. It is to be noted that as the light source 21, excimer laser is optimum such as an XeCl excimer laser light source which emits pulse light having a wavelength of 308 nm, KrF excimer laser which emits pulse light having a wavelength of 248 nm, and ArF laser which emits pulse light having a wavelength of 193 nm. Furthermore, the light source 21 may be a YAG laser light source. As the light source 21, another appropriate light source is usable which outputs energy for melting the non-single-crystal semiconductor film, for example, the amorphous silicon film 4. The homogenizer 22 is disposed on the optical axis of the laser light emitted from the light source 21.

In the homogenizer 22, for example, a beam expander 23, first fly eye lens 24, first optical capacitor system 25, second fly eye lens 26, and second optical capacitor system 27 are disposed on the optical axis of the laser light from the light source 21. The homogenizer 22 homogenizes the laser light emitted from the light source 21 with respect to light intensity, and incidence angle upon the phase modulation element 16 in a section of a luminous flux.

That is, in the illumination system 15, the laser light emitted from the light source 21 is enlarged via the beam expander 23, and thereafter enters the first fly eye lens 24. A plurality of light sources are formed on a rear-side focal plane of the first fly eye lens 24. The luminous flux from the plurality of light sources illuminates an incidence plane of the second fly eye lens 26 via the first optical capacitor system 25 in a superimposition manner. As a result, a larger number of light sources are formed on the rear-side focal plane of the second fly eye lens 26 as compared with that of the first fly eye lens 24. The luminous flux from a large number of light sources formed on the rear-side focal plane of the second fly eye lens 26 enters and illuminates the phase modulation element 16 via the second optical capacitor system 27.

As a result, the first fly eye lens 24 and the first optical capacitor system 25 of the homogenizer 22 constitute a first homogenizer, and homogenize the laser light entering the phase modulation element 16 with respect to the incidence angle. The second fly eye lens 26 and the second optical capacitor system 27 constitute a second homogenizer, and the second homogenizer homogenizes the laser light from the first homogenizer, whose incidence angle has been homogenized, with respect to light intensity in each position in the plane of the phase modulation element 16. Thus, the illumination system 22 forms laser light having a substantially uniform light intensity distribution, and the phase modulation element 16 is irradiated with this laser light.

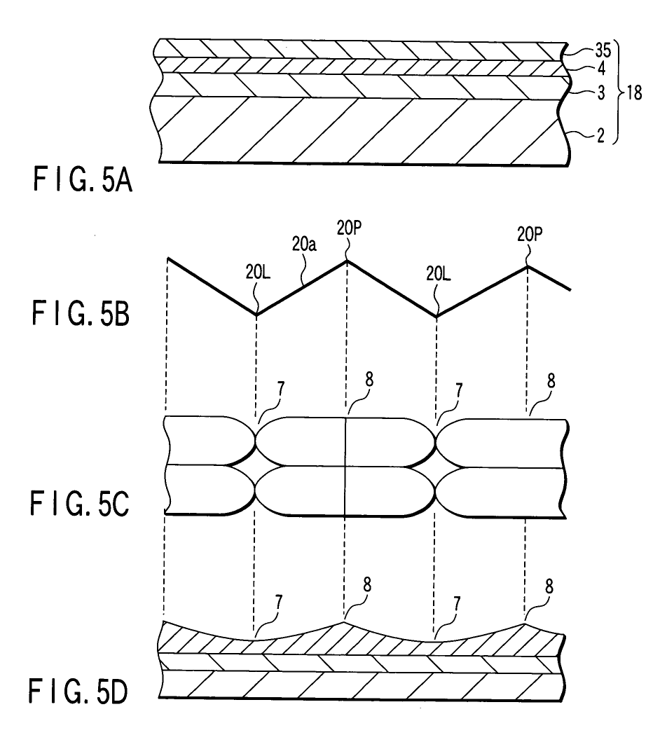

The phase modulation element 16, for example, a phase shifter is an optical element which modulates a phase of light emitted from the homogenizer 22 and which emits a laser beam having a minimum light intensity distribution having an inversed peak shape as shown in FIG. 5B. FIG. 5B enlarges and shows a part of the minimum light intensity distribution having the inversed peak shape. In FIG. 5B, the abscissa indicates a place (position in an irradiated plane), and the ordinate indicates light intensity (energy).

The phase shifter 16 causes diffraction and interference of laser light in a boundary of a stepped portion disposed in a transparent article such as a quartz base material, and imparts a periodic space distribution to laser light intensity. The phase shifter makes a phase difference of 180° on opposite sides of, for example, the boundary of the stepped portion x=0. In general, assuming that the wavelength of the laser light is λ, a film thickness of a transparent medium is given by t=λ/2(n−1) in order to form the transparent medium having a refractive index n on the transparent base material and makes a phase difference of 180°. Assuming that the refractive index of the quartz base material is 1.46, a wavelength of XeCl excimer laser light is 308 nm. Therefore, to make a phase difference of 180°, a stepped portion of 334.8 nm is formed by a method such as etching.

Moreover, when an SiNx film is formed as the transparent medium by PECVD, LPCVD and the like, and the refractive index of the SiN film is set to 2.0, the SiN film may be formed into 154 nm on the quartz base material, and the stepped portion may be formed by the etching. The intensity of the laser light passed through the phase shifter 16 to which a phase of 180° is attached indicates a periodic intensity pattern.

In this embodiment, a mask in which the stepped portion itself is repeatedly/periodically formed is a periodical phase shifter. A width of the phase shift pattern and a distance between the patterns are both, for example, 3 μm. The phase difference does not have to be necessarily 180°, and may be such a phase difference that can realize the intensity of the laser light.

The laser light whose phase has been modulated by the phase modulation element 16 enters the substrate 18 to be crystallized via the optical image forming system 17. Here, in the optical image forming system 17, the pattern face of the phase modulation element 16 and the substrate 18 to be crystallized are disposed in an optically conjugated manner. In other words, a height position of the stage 19 is corrected in such a manner as to set the substrate 18 to be crystallized to the face (image plane of the optical image forming system 17) optically conjugated with the pattern face of the phase modulation element 16. The optical image forming system 17 comprises an aperture stop 33 between positive lens groups 31 and 32. The optical image forming system 17 is an optical lens which magnifies or reduces an image of the phase modulation element 16, for example, to ⅕ to reduce the image on the substrate 18 to be crystallized.

The aperture stop 33 has a plurality of aperture stops having different sizes of apertures (light transmitting portions). The plurality of aperture stops 33 may be constituted in such a manner as to be replaceable with respect to an optical path. Alternatively, the aperture stop 33 may have an iris diaphragm capable of continuously changing the size of the aperture. In any case, the size of the aperture of the aperture stop 33 (i.e., an image-side numerical aperture NA of the optical image forming system 17) is set in such a manner as to generate a required light intensity distribution on the semiconductor film of the substrate 18 to be crystallized as described later. It is to be noted that the optical image forming system 17 may be a refractive or reflective optical system, or a refracto-reflective optical system.

Moreover, in the substrate 18 to be crystallized, as shown in FIG. 5A, the silicon oxide film 3, amorphous silicon film 4, and cap film 35 are successively formed as a substrate insulating film by a chemical vapor development (CVD) process or a sputtering process, for example, on the plate glass 2 for a liquid crystal display. As to the substrate insulating film, for example, SiO₂ is formed into a film thickness of 500 to 1000 nm. The substrate insulating film prevents the amorphous silicon film 4 from being brought into direct contact with the glass substrate 2, and prevents foreign matters such as Na deposited from the substrate 2 from being mixed into the amorphous silicon film 4. Furthermore, the film prevents heat at melting temperature in the crystallization step of the amorphous silicon film 4 from being directly conducted to the glass substrate 2, and contributes to the crystallization of large particle diameter by a heat accumulating effect at the melting temperature.

The amorphous silicon film 4 is a crystallized film, and a film thickness of, for example, 30 to 250 nm is selected. The cap film 35 accumulates the heat generated when the amorphous silicon film 4 is molten in the crystallization step, and this heat accumulating function contributes to formation of the crystallized region having a large particle diameter. This cap film 35 is an insulating film, for example, a silicon oxide film (SiO₂), and film thickness is 100 nm to 400 nm, for example, 300 nm.

The substrate 18 to be crystallized is automatically conveyed onto the stage 19 of the crystallization device, positioned and disposed in a predetermined position, and held by a vacuum chuck, electrostatic chuck or the like.

Next, a crystallization process will be described with reference to FIGS. 1 to 7G. The pulse laser light emitted from the laser light source 21 enters the homogenizer 22, and the light intensity of the laser light and the incidence angle upon the phase modulation element 16 are homogenized. That is, the homogenizer 22 expands the laser beam incident from the light source 21 in a horizontal direction to form a linear (e.g., linear length of 200 mm) laser beam, and homogenizes the light intensity distribution. For example, a plurality of X-direction cylindrical lenses are arranged in a Y-direction, a plurality of luminous fluxes arranged in the Y-direction are formed, and each luminous flux is re-distributed by another X-direction cylindrical lens. A plurality of Y-direction cylindrical lenses are similarly arranged in an X-direction, a plurality of luminous fluxes arranged in the X-direction are formed, and each luminous flux is re-distributed by another Y-direction cylindrical lens.

The laser light is an XeCl excimer laser light having a wavelength of 308 nm, and a pulse continuing time per shot is 20 to 200 ns. When the phase modulation element 16 is irradiated with the pulse laser light on the above-described conditions, the pulse laser light which has entered the periodically formed phase modulation element 16 causes diffraction and interference in the stepped portion. As a result, as shown in FIG. 5B, the phase modulation element 16 generates a periodically changing light intensity distribution of intensity having an inverted peak pattern.

In the light intensity distribution of the intensity having the inverted peak pattern, the laser light intensity for melting the amorphous silicon film 4 from a minimum light intensity to a maximum light intensity is preferably output. The pulse laser light passed through the phase modulation element 16 is focused on the substrate 18 to be crystallized by the optical image forming system 17 to enter the amorphous silicon film 4.

That is, most of the incident pulse laser light passes through the cap film 35, and is absorbed by the amorphous silicon film 4. As a result, the irradiated region of the amorphous silicon film 4 is heated and molten. The heat at this melting time is accumulated by the cap film 35 and the silicon oxide film 3.

In a period of time when the irradiation of the pulse laser light is interrupted, the irradiated region tries to lower the temperature at high speed, but a temperature drop speed is remarkably moderate by the heat accumulated by the cap film 35 and the silicon oxide film 3 disposed on the front/back surface. At this time, the temperature of the irradiated region drops in accordance with the light intensity distribution having the inverted peak pattern generated by the phase modulation element 16, and the crystals successively grow in the transverse direction.

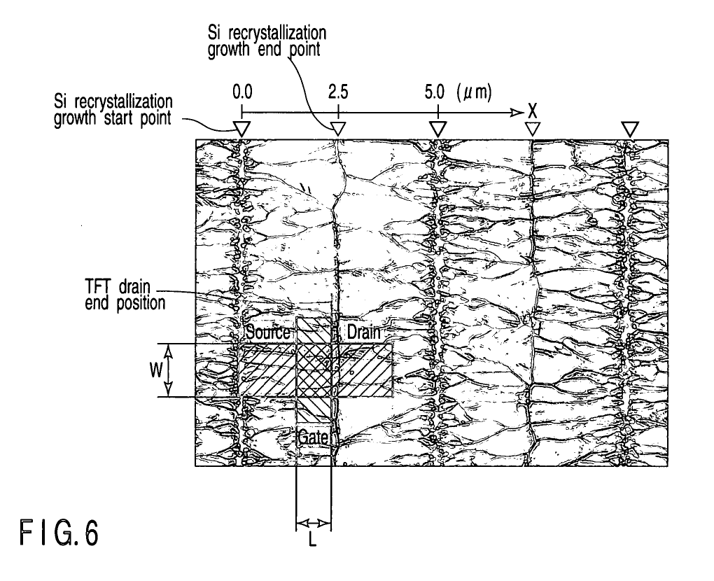

In other words, a solidifying position in the molten region in the irradiated region successively moves toward high-temperature side from low-temperature side. That is, as shown in FIGS. 5C, 5D, and 6, the grains grow from the lateral growth start position 7 toward the lateral growth edge position 8. In this case, as shown in FIG. 5D, a slight protrusion is generated in the vicinity of the lateral growth edge position 8 of the irradiated region. FIG. 5C is a plan view showing the shape of the crystallized region 5 in the amorphous silicon film 4 after the cap film 35 is peeled off. FIG. 5C shows a configuration in which the grains grow in the transverse direction from the lateral growth start position 7 to the lateral growth edge position 8.

FIG. 5D is a sectional view of FIG. 5C. FIG. 5D shows that the film thickness of the semiconductor thin film 4a increases from the lateral growth start position 7 toward the lateral growth edge position 8, the inclined face having a vertex in the lateral growth edge position 8 is formed, and the region is crystallized into a peaked sectional shape. FIG. 5D shows a case where there are a plurality of inversed peaked light intensity distribution patterns as shown in FIG. 5B. In a single inversed peaked light intensity distribution pattern, the film thickness distribution changes in a peaked shape only in one protruding portion.

Thus, the crystallization step by one pulse laser light ends. The crystallized region where the crystals have been grown has a size sufficient for storing one or a plurality of function elements. FIGS. 5B, 5C, 5D show interrelation by dotted lines. That is, FIGS. 5B, 5C, 5D show a state in which the grains start growing in inversed peak portions 20L (lateral growth start positions 7) of FIG. 5B, and positive peak portions 20P are end positions (lateral growth edge positions 8) of lateral growth. A single-crystal-silicon film thickness successively increases from the lateral growth start position 7 to the lateral growth edge position 8, and the film is raised in the vicinity of the end position 8.

The crystallization device automatically irradiates the crystallized region of the next amorphous silicon film 4 with pulse laser light 20 by a program stored beforehand. As to the moving to the next crystallized region, for example, the stage 19 can be moved to select the position. Needless to say, in the movement of the crystallized position, the substrate 18 to be crystallized and the light source 21 can be relatively moved to select the position.

When the crystallized region is selected, and the positioning is completed, the next pulse laser light is emitted. When this shot of the laser light 20 is repeated, a broad range of the substrate 18 to be crystallized can be crystallized. The amorphous silicon film 4 in which the crystallized region has been formed is the semiconductor thin film 4a. The crystallization step ends in this manner.

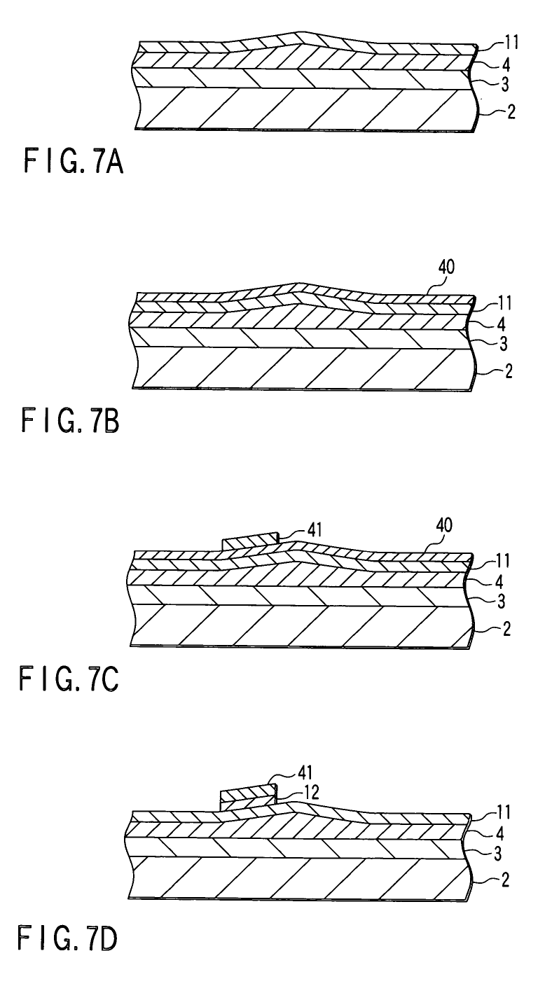

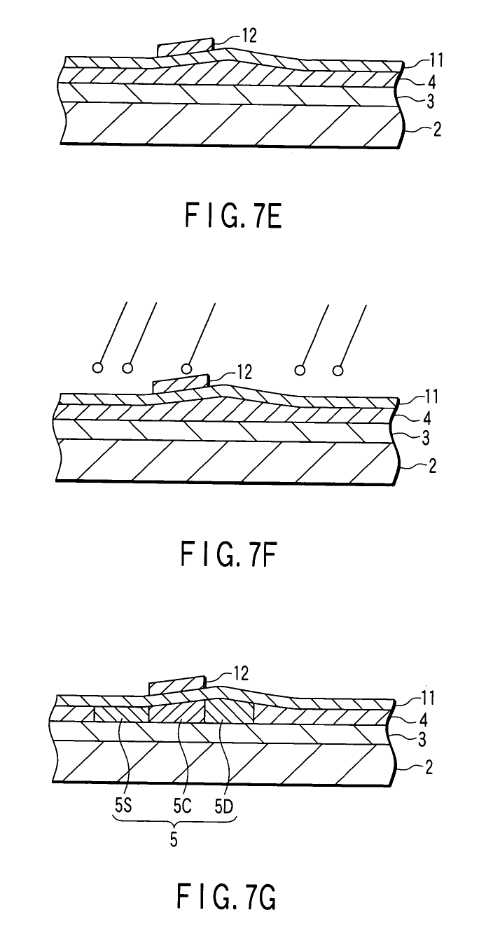

Next, an example of the steps of manufacturing the TFT with respect to the substrate subjected to the crystallization step in and after the step S8 shown in FIG. 2 will be described with reference to FIGS. 6 and 7. The same parts as those of FIGS. 1 to 5 are denoted with the same reference numerals, and detailed description is omitted.

The SiO₂ film which is the cap film 35 is formed on the surface of the substrate whose crystallization step has ended. This SiO₂ film is also usable as the gate insulating film of the TFT. To avoid mixture of foreign matters by abrasion or the like from the amorphous silicon film 4 in the crystallization step, the SiO₂ film is etched/removed. This example is an example in which the film is removed.

As shown in FIG. 7A, a gate insulating film 11, for example, an SiO₂ film is formed on the semiconductor thin film 4a which is the surface of the substrate after the cap film 35 is removed. The gate insulating film 11 is a silicon oxide film having a thickness of 80 nm and deposited on the semiconductor thin film 4a, for example, by an LP-CVD process. The LP-CVD is performed, for example, on conditions at a substrate temperature of 500° C. for a deposition time of 45 minutes.

Next, a step of forming the gate electrode 12 is performed. That is, as shown in FIG. 7B, a gate electrode layer, for example, an aluminum layer 40 is formed on the gate insulating film 11. The aluminum layer 40 is deposited, for example, into a thickness of 100 nm on a silicon oxide film (SiO₂ film) of the gate insulating film 11 by sputtering. Sputtering conditions are, for example, a substrate temperature at 100° C. and a deposition time of ten minutes.

When the aluminum layer 40 is selectively etched to form the gate electrode 12 in a predetermined position, a resist pattern 41 is formed on the aluminum layer 40. As to this resist pattern 41, the aluminum layer 40 is coated with a resist film, this resist film is selectively exposed using a photo mask, and the resist film is removed leaving a mask region for the gate electrode to thereby form the resist pattern 41 as shown in FIG. 7C. A position of the resist pattern 41 for forming the gate electrode 12 is important. The resist pattern 41 is positioned in the vicinity of the lateral growth edge position 8, and formed.

Next, the aluminum layer 40 is removed, for example, dry-etched using the resist pattern 41 as a mask to thereby form the gate electrode 12 as shown in FIG. 7D. In this dry etching, for example, BCl₃ and CH₄ are used as etching gases. Subsequently, the resist pattern 41 on the gate electrode 12 is removed as shown in FIG. 7E.

Next, impurities are added to the semiconductor thin film 4a using the gate electrode 12 as a mask. When the poly-silicon TFT is formed into an n-channel type, phosphor is ion-implanted as the impurities into the semiconductor thin film 4a. When the poly-silicon TFT is formed into a p-channel type, boron is ion-implanted into the semiconductor thin film 4a. For example, a logical circuit such as a CMOS inverter comprises a combination of an n-channel type polysilicon TFT and a p-channel type poly-silicon TFT. Therefore, the ions are implanted into one of the n-channel type poly-silicon TFT and the p-channel type poly-silicon TFT in a state in which the semiconductor thin film 4a of the other poly-silicon TFT is covered with a mask such as a resist for inhibiting undesired ion implantation.

After implanting the ions into the n-channel type poly-silicon TFT and the p-channel type poly-silicon TFT, respectively, the semiconductor thin film 4a is activated by the annealing. The annealing is a treatment, for example, in a nitrogen atmosphere at a substrate temperature of 600° C. for three hours. As a result, the source region 5S and the drain region 5D having high impurity concentrations are positioned on the opposite sides of the gate electrode 12, and formed in the semiconductor thin film 4a.

As a result, a channel region 5C side edge portion 10 of the source region 5S or the drain region 5D is positioned in the vicinity of the lateral growth edge position 8, and formed as shown in FIG. 7F.

Next, an interlayer insulating film is formed on the gate insulating film 11 and the gate electrode 12, and a source electrode, drain electrode, wiring of the gate electrode 12 and the like are formed by a known method to form the TFT 1.

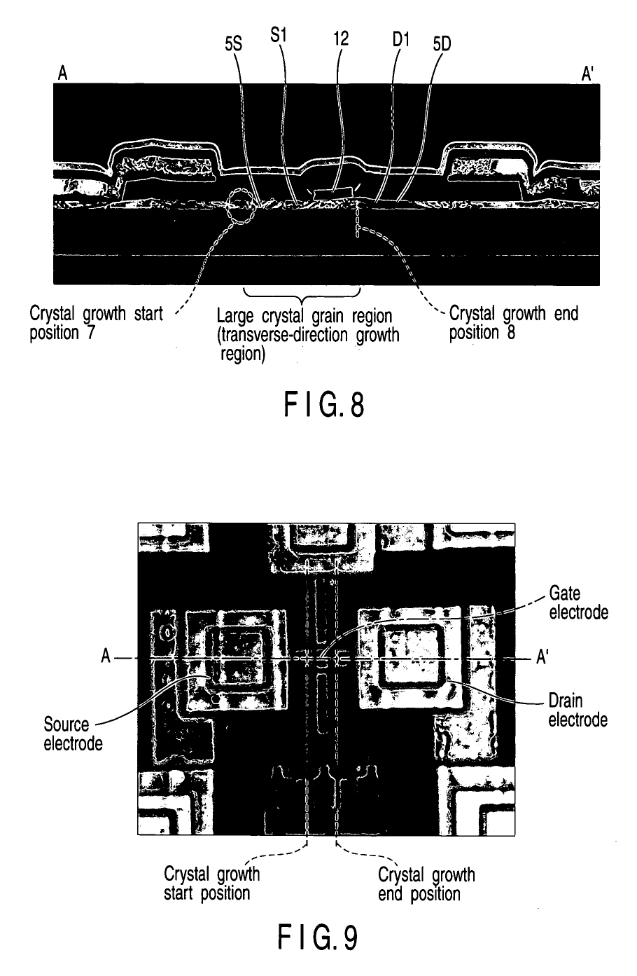

A sectional structure of the TFT 1 manufactured in this manner is as shown in FIG. 8. FIG. 8 is a microscope photograph showing that the lower channel region 5C side edge portion 10 of the gate electrode 12 of the source region 5S is disposed in the vicinity of the lateral growth edge position 8 of the crystallized region. Furthermore, it is seen that laminate defects S1, D1 running from a deep direction of the semiconductor thin film 4a toward a shallow direction are generated in the source region 5S and the drain region 5D of the TFT 1. Furthermore, it is well seen that the gate electrode 12 tilts.

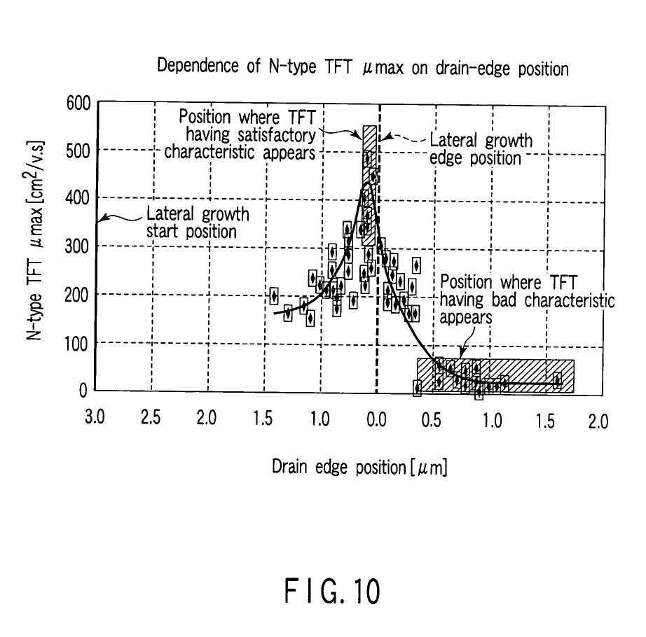

FIG. 9 is a plan view of FIG. 8, showing that the end portion 10 of the drain region 5D on the side of the channel region 5C is disposed in the vicinity of the lateral growth edge position 8. A relation between a position where the channel region 5C side edge portion 10 of the drain region 5D is formed in the vicinity of the lateral growth edge position 8, and an electron or hole mobility μ of the n-type TFT is shown in FIG. 10 with respect to the TFT 1 formed as described above.

As shown in FIG. 10, a characteristic of 150 cm²/v.s or more is obtained as the mobility of the TFT 1 in which the channel region SC side edge portion 10 of the drain region 5D is disposed within 1.5 μm from the lateral growth edge position 8. Especially, a superior characteristic of 300 cm²/v.s or more is obtained as the mobility in the TFT 1 in which the channel region 5C side edge portion 10 of the drain region 5D is formed within 0.05 to 0.2 μm from the lateral growth edge position 8.

In FIG. 10, a large number of n-type TFT mobility characteristics are plotted. This characteristic is a mobility characteristic of the TFT in which a drain edge position (the channel region side edge portion of the drain region 5D) of the n-type TFT is formed within 1.5 μm from the lateral growth edge position 8. Furthermore, a characteristic plotted by squares is a mobility characteristic of the TFT in which a source end position (the channel region side edge portion of the source region 5S) of the n-type TFT is formed within 1.5 μm from the lateral growth edge position 8. This mobility characteristic is obtained from a characteristic curve of a drain current (ordinate) with respect to a gate voltage (abscissa). A substantially matched characteristic is obtained in the TFT in which the drain edge position or the source end position is disposed in the vicinity of 1.5 μm or less from the lateral growth edge position 8.

In FIG. 10, data plotted outside the lateral growth edge position 8 (vicinity of end position 8 of the adjacent crystallized region) is a characteristic of a TFT whose channel region is formed over the lateral growth edge position 8. The characteristic of FIG. 10 is the characteristic of the n-type TFT, but a similar characteristic can be obtained even in the p-type TFT. Furthermore, a direction of current flowing through the TFT 1 of the embodiment is parallel to a growth direction in which the crystals have grown in the transverse direction, and it is optimum to pass the current in the lateral growth direction.

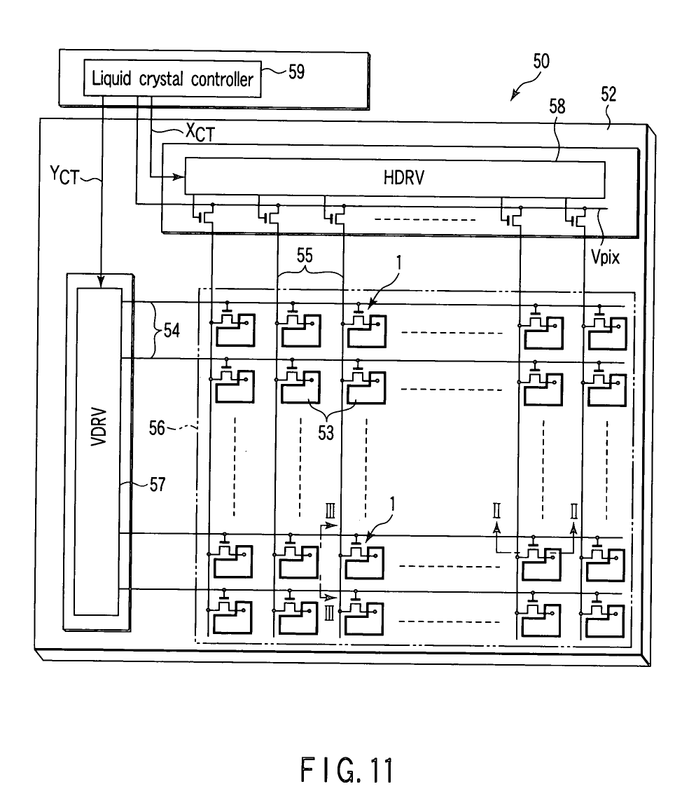

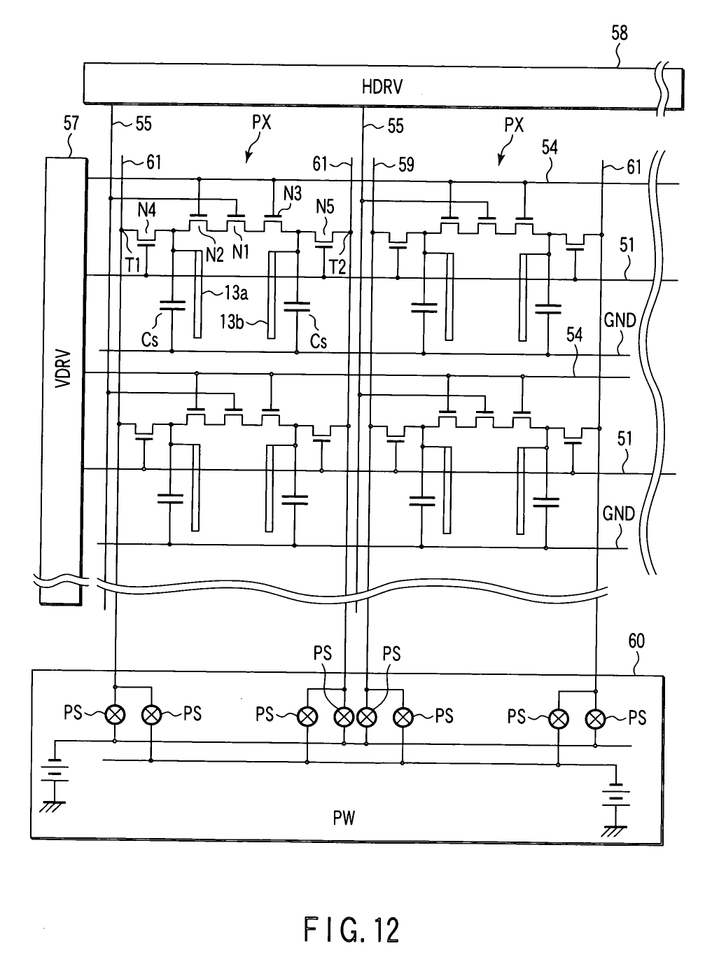

Next, an embodiment applied to a transistor circuit of a display device, for example, a LCD will be described with reference to FIGS. 11 and 12. The same parts as those of FIGS. 1 to 10 are denoted with the same reference numerals, and detailed description is omitted. FIGS. 11 and 12 show an example of an equivalent circuit of an active matrix type LCD 50. The liquid crystal display 50 comprises: a transparent substrate 52; pixel electrodes 53; scanning lines 54; signal lines 55; an opposed electrode 56; the TFT 1; a scanning line driving circuit (VDRV) 57; a signal line driving circuit (HDRV) 58; a liquid crystal controller 59; a power supply circuit 60; power supply wires 61 and the like.

That is, a peripheral circuit portion requiring a high-speed operation like the VDRV 57 and the HDRV 58 comprises the thin film transistor. As shown in FIG. 12, each pixel circuit PX has first and second power supply terminals T1, T2, second pixel electrodes 13a, 13b, and first to fifth transistors N1, N2, N3, N4, N5. The power supply terminals T1, T2 are set to reverse-polarity potentials having a predetermined level difference from a reference potential, respectively. The reference potential is equal to the potential of a common electrode GND for grounding with respect to all the pixel circuits PX. The first pixel electrode 13a is capacitive-coupled to the common electrode GND to constitute a first auxiliary capacity Cs. Accordingly, the pixel electrodes 13a, 13b hold electric charges supplied from the first and second power supply terminals T1, T2, and a potential difference obtained by these charges is applied, to a liquid crystal layer, as a liquid crystal driving voltage for generating a substantially transverse-direction electric field in the liquid crystal layer.

The first transistor N1 has a gate which receives a video signal, and is an input transistor which re-distributes the electric charges held by the first and second pixel electrodes 13a, 13b in response to the video signal. The liquid crystal driving voltage is held by a liquid crystal capacity CLC between the first and second pixel electrodes 13a, 13b. The second to fifth transistors N2, N3, N4, N5 are connection transistors, and constitute a switch circuit. The fourth and fifth transistors N4, N5 electrically connect the first and second pixel electrodes 13a, 13b to the first and second power supply terminals T1, T2 in order to precharge the first and second pixel electrodes 13a, 13b into potentials of the first and second power supply terminals T1, T2 at a conduction time. In the first transistor N1, the first and second pixel electrodes 13a, 13b are connected to one end and the other end of a current path of the first transistor N1, respectively, in order to redistribute the electric charges held by the first and second pixel electrodes 13a, 13b.

Specifically, each of the transistors N1 to N5 comprises an N-channel thin film transistor (TFT). The respective pixel electrodes 13a, 13b are connected to sources 5S of the transistors N4, N5, respectively. A gate 5G of the first transistor N1 is connected to a video signal wire 55, the drain 5D of the transistor N1 is connected to that of the second transistor N2, and the source 5S of the transistor N1 is connected to the drain 5D of the third transistor N3. The gates 5G of the transistors N2, N3 are connected to the scanning lines 54, and the gates 5G of the transistors N4, N5 are connected to a precharge control wiring 51. The drains 5D of the transistors N4, N5 are connected to the power supply terminals T1, T2, respectively.

Furthermore, in a substrate 52, a plurality of pairs of power supply wires 61, 61 are arranged along a row of the pixel circuit PX in the same manner as in a plurality of video signal wires 55. The power supply terminals T1, T2 of each pixel circuit PX correspond to branch points disposed in a pair of power supply wires 61, 61, respectively. These power supply wires 61 are connected to a power supply circuit (PW) 60.

Each of the VDRV 57 and the HDRV 58 is formed as a driver LSI into a unit. The VDRV 57 generates a selection pulse power supplies Vg and Vpc to select a row of the pixel circuit PX, and successively supplies the powers to a plurality of scanning lines 54 and a plurality of precharge control wires 51. In the selected row, the selection pulse voltage Vpc is output prior to the selection pulse voltage Vg. The HDRV 58 supplies a video signal for one horizontal line to a plurality of video signal lines 55 in a duration of the selection pulse voltage Vg.

The TFT 1 capable of realizing a system display containing active elements such as a peripheral circuit portion and a memory circuit portion is formed into a structure shown in FIG. 1 to constitute the VDRV 57 or the HDRV 58 requiring the high-speed operation of the display 50. The peripheral circuit portion of the VDRV 57 or the HDRV 58 preferably comprises a TFT in which the source end position of the source 5S or the drain edge position of the drain region 5D is formed is formed within 0.05 to 0.2 μm from the lateral growth edge position 8. That is, each of the peripheral circuits 57, 58 may comprise a TFT having a superior characteristic of 300 cm²/v.s or more as the mobility (μmaX).

The display device manufactured in this manner is capable of realizing the system display containing the active elements like the peripheral circuit and the memory circuit. This display device is also effective for miniaturizing and lightening.

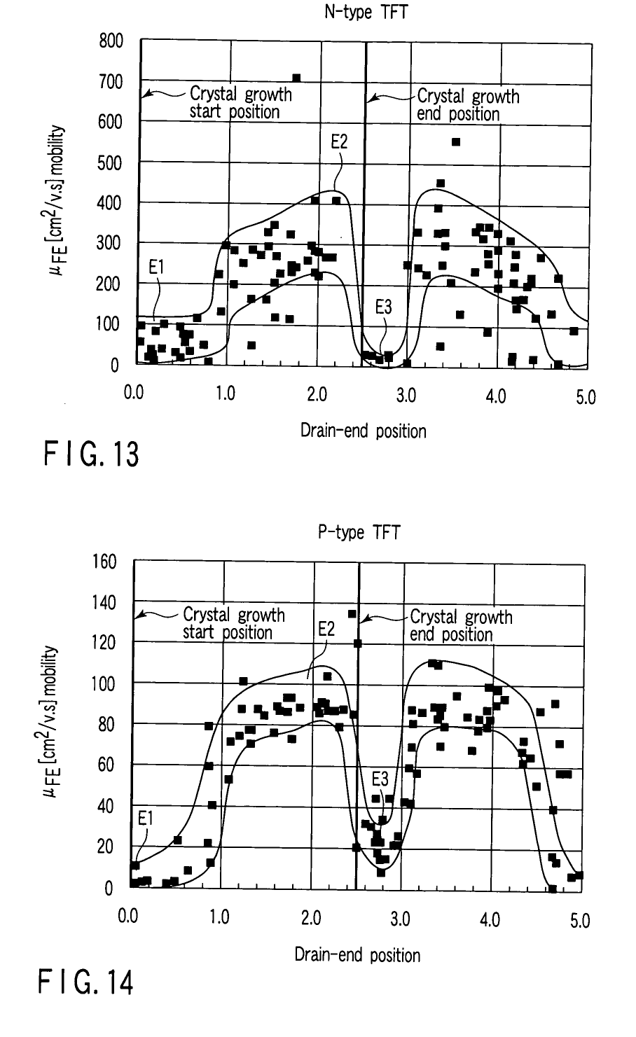

Next, another example of a thin film transistor (TFT) will be described with reference to FIGS. 13 to 15. FIG. 13 is a diagram of a characteristic of mobility at a time when a position of a bonded portion (drain edge position) of the drain region of the n-type TFT with respect to the channel region is changed between the lateral growth start point and the lateral growth edge point to manufacture a large number of TFTs. This TFT has a structure of the TFT shown in FIG. 1. The diagram is a mobility characteristic diagram of the TFT in which the glass substrate 2 is formed by a P-type silicon wafer substrate having a thickness of, for example, 625 μm. A film thickness of the channel region at this time is 200 mm.

In the n-channel type TFT, the mobility rises in the drain edge position of about 0.8 μm from the lateral growth start point, and high mobility is obtained in a position up to 2.3 μm. Especially, in the TFT in which a drain edge is formed in the drain edge position of about 1.6 μm from the lateral growth start point, a mobility of 760 cm²/v.s is obtained. These characteristics are obtained at a time when a length from the lateral growth start position 7 to the lateral growth edge position 8 shown in FIGS. 5C, 5D, 6 is 2.5 μm. The length from the lateral growth start position 7 to the lateral growth edge position 8 is determined by a pulse width of the light intensity distribution having the inversed peak shape as shown in FIG. 5B. A technique has been established capable of mass-producing crystallized regions in each of which the length from the lateral growth start position 7 to the lateral growth edge position 8 is, for example, 5 μm.

It has been confirmed that the drain edge position indicating an optimum mobility shown in FIG. 13 indicates a characteristic twice the data shown in FIG. 13 in a case where the length from the lateral growth start position 7 to the lateral growth edge position 8 is 5 μm. That is, in the n-channel-type TFT, the mobility rises in the drain edge position of about 1.6 μm from the lateral growth start point, and high mobility is obtained in a position up to 4.6 μm.

A mobility characteristic example of the p-channel-type TFT with respect to the drain edge position is shown in FIG. 14. As shown in FIG. 14, the mobility rises where the drain edge position indicating the optimum mobility is about 1 μm from the lateral growth start point, and a high mobility is obtained in a position up to 2.3 μm. This characteristic is also obtained in a case where the length from the lateral growth start position 7 to the lateral growth edge position 8 is 2.5 μm in the same manner as in FIG. 13.

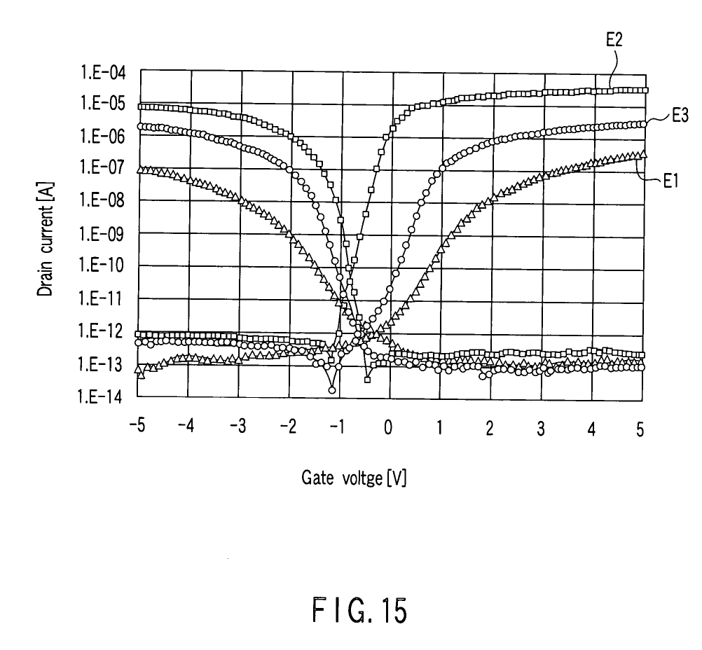

FIG. 15 is a characteristic curve diagram showing a relation of a drain current with respect to a gate voltage in a TFT in which drain edge positions are formed in a position E1 in the vicinity of the lateral growth start point, an optimum position E2 of the mobility, and a position E3 in the vicinity of the lateral growth edge point. As shown in FIG. 15, the optimum characteristic is shown in the optimum position E2 of the mobility. The relation of the position E1 in the vicinity of the lateral growth start point, the optimum position E2 of the mobility, and the position E3 in the vicinity of the lateral growth edge point is common to FIGS. 13 to 15.

The thin film transistor 1 of each circuit, and the memory, capacitor, resistance and the like replaced with the thin film transistor may comprise the thin film transistor of FIG. 1. That is, it is assumed that, in this specification, the thin film transistor includes a thin film transistor which can comprise the thin film transistor shown in FIG. 1 regardless of a function.

A thin film transistor 26 manufactured in this manner is applicable to a driving circuit for a liquid crystal display (LCD), electroluminescence (EL) display or the like, an integrated circuit for a memory (SRAM or DRAM) or a CPU in each pixel circuit and the like.

As described above, according to the above-described embodiment, a TFT having high electron or hole mobility can be obtained. The TFT capable of obtaining this high mobility is applicable to the peripheral circuit portion like the VDRV 57, HDRV 58 or the like.

What is claimed is:

1. A thin film transistor having a source region, a channel region, and a drain region in a semiconductor thin film whose grains have grown in a lateral direction crossing a thickness direction, the thin film transistor having a gate insulating film and a gate electrode in an upper part of the channel region,
wherein a channel-region-side edge portion of at least one of the drain region and the source region is disposed in such a manner as to be positioned in the vicinity of an end position of the lateral growth.

2. A thin film transistor having a source region, a channel region, and a drain region in a semiconductor thin film having an inclined face raised in a growth edge direction of grains which have grown in a lateral direction crossing a thickness direction, the thin film transistor having a gate insulating film and a gate electrode in an upper part of the channel region,
wherein a channel-region-side edge portion of at least one of the drain region and the source region is disposed in such a manner as to be positioned in the vicinity of a vertex of the inclined face.

3. A thin film transistor having a source region, a channel region, and a drain region in a semiconductor thin film having an inclined face whose film thickness increases toward a lateral growth edge point in a silicon film growing in a lateral growth direction from a lateral growth start position, the thin film transistor having a gate insulating film and a gate electrode in an upper part of the channel region,
wherein a channel-region-side edge portion of at least one of the drain region and the source region is disposed in such a manner as to be positioned in the vicinity of a vertex of the semiconductor thin film whose film thickness increases.

4. The thin film transistor according to claim 1, wherein a laminate defect exists in the vicinity of the end position of the lateral growth.

5. The thin film transistor according to claim 2, wherein a laminate defect exists in the inclined face of the semiconductor thin film.

6. The thin film transistor according to claim 3, wherein a laminate defect exists in the inclined face of the semiconductor thin film.

7. The thin film transistor according to claim 1, wherein the vicinity of the end position of the lateral growth is a position within a range of 0.05 to 0.2 μm from the end position of the lateral growth.

8. The thin film transistor according to claim 2, wherein the vicinity of the vertex of the inclined face of the semiconductor thin film is a position within a range of 0.05 to 0.2 μm from the vertex of the inclined face of the semiconductor thin film.

9. The thin film transistor according to claim 3, wherein the vicinity of the vertex of the inclined face of the semiconductor thin film is a position within a range of 0.05 to 0.2 μm from the vertex of the inclined face of the semiconductor thin film.

10. The thin film transistor according to claim 1, comprising a crystallized semiconductor thin film whose film thickness is longest in the end position of the lateral growth and whose film thickness monotonously decreases in an extended direction.

11. The thin film transistor according to claim 2, comprising a crystallized semiconductor thin film whose film thickness is longest in a vertex portion of the inclined face of the semiconductor thin film and whose film thickness monotonously decreases in an extended direction.

12. The thin film transistor according to claim 3, comprising a crystallized semiconductor thin film whose film thickness is longest in a vertex portion of the inclined face of the semiconductor thin film and whose film thickness monotonously decreases in an extended direction.

13. A method of manufacturing a thin film transistor, comprising: a step of irradiating a non-single crystal semiconductor film with modulation laser light having inverted-peaked light intensity distribution to form a crystallized semiconductor thin film whose section has a peaked shape in an irradiated region; and a step of positioning a channel-region-side edge portion of at least one of a drain region and a source region in the vicinity of a vertex port-ion of the peaked-shaped crystallized semiconductor thin film to form the thin film transistor in the positioned portion.

14. A display device comprising: the thin film transistor according to claim 1 in a peripheral circuit portion requiring a high-speed operation.

15. A display device comprising: the thin film transistor according to claim 2 in a peripheral circuit portion requiring a high-speed operation.

16. A display device comprising: the thin film transistor according to claim 3 in a peripheral circuit portion requiring a high-speed operation.
